(19) United States
(12) Patent Application Publication
(10) Pub. No.: US 2006/0139123 A1
(43) Pub. Date: Jun. 29, 2006

(54) Resistive capacitor structure for anti-resonance reduction

(75) Inventor: George Tang, Cupertino, CA (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/025,210

(22) Filed: Dec. 29, 2004

(51) Int. Cl. H03H 7/01

(52) U.S. Cl. 333/172

(57) ABSTRACT

A resistive capacitor structure adding series resistance to a decoupling capacitor for improved decoupling of power and ground plane noise signals. The resistive capacitor couples a resistor in series with the capacitor where the resistor provides high resistance without substantially increasing inductance to thereby dampen anti-resonance noise typically generated when multiple decoupling capacitors are used for filtering a broader range of possible noise signal frequencies. In one aspect, the resistor comprises magnetic material or other low conductivity material, such as iron, having a small skin depth characteristic to thereby reduce the inductance while still providing high resistivity required to dampen anti-resonance noise. The resistive element may be discrete with respect to the decoupling capacitor or may be integral therewith as one of the plates of the decoupling capacitor. The resistive capacitor plates may be integral with and form a part of the power and ground planes of a circuit board.

### BACKGROUND OF THE INVENTION

1. Field of the Invention

The present convention relates generally to capacitive circuit structures useful in noise decoupling circuits. Resistance may be added to a capacitive structure to reduce anti-resonance noise. In one aspect, multiple resistive capacitors may be utilized to decouple signals from power and ground noise while reducing the anti-resonance effects presently seen in the art. One of the multiple resistive capacitors may be the capacitor structure formed by power and ground planes enhanced with added resistance.

2. Discussion of Related Art

Most present day electronics systems utilize power and ground signals generated by a switched power supply that converts readily available power voltages into required direct current voltages. The switching features of such power supplies operate at a variety of frequencies and often generate noise derived from those frequencies that may be induced or otherwise unintentionally applied to a signal path. Other switched signals such as integrated circuits on the circuit board design can also generate noise signals where multiple output signals are switching simultaneously. All such noise is often generically referred to as simultaneous switching noise or “SSN”. As used herein, noise refers to any source of switching noise either from switching power supplies or from IC simultaneous switching outputs.

It is common for circuit designers to utilize decoupling capacitors to help remove or reduce these various forms of noise applied to signal paths in a circuit design. A decoupling capacitor may be applied to filter out the unwanted noise signals from the power plane, ground plane, or other signal paths of the circuit.

In general, a single decoupling capacitor is useful for filtering out such noise signals within a relatively narrow band of frequencies. Above or below that narrow band of frequencies, the decoupling capacitor may be of limited or no use as a filter. Although a particular application may be analyzed by a design engineer and a narrow frequency range of unwanted noise signals may be identified and filtered out by a single decoupling capacitor, changes or upgrades in the application circuit over time may shift the noise frequency or may add additional noise signals at other frequencies. The noise frequency may shift or additional frequencies may be generated based upon load and other factors associated with the application circuit as it evolves over time. Therefore, selecting a single capacitor for such decoupling applications may not successfully filter all noise signals over a wide range of frequencies or multiple frequencies.

In view of such limitations, electrical designers frequently analyze the application electrical circuit to determine a broader range of possible frequencies and to determine how the noise signal frequencies may shift over time or what additional noise signal frequencies may arise. Multiple decoupling capacitors may then be applied to the circuit design in parallel, each capacitor dampening a corresponding range of frequencies. However, utilizing multiple capacitors of different capacitance values, each intended to reduce or dampen a different range of noise frequencies, may cause ringing of some signals of the circuit design. In other words, using multiple capacitors to help filter power and ground signals may, in and of itself, amplify other noise signals as a resonant signal. This may happen due to impedance peaks created by the multiple capacitors. Noise amplified by this impedance is often referred to as “anti-resonance”.

In general, commercial manufacturers design and produce capacitors having a lower electrical series resistance (“ESR”) in an attempt to lower the capacitor's impedance. However, utilizing such capacitors in a multiple capacitor structure to cover a broad range of frequencies only further exacerbates the anti-resonance problem.

Inability to effectively filter power and ground signals without significant generation of anti-resonance related noise signals can create catastrophic failures in the electrical system. For example, in the context of a computer or digital electronics system, high frequency operational logic signals transmitted or received representing rapidly changing data may result in SSN (noise). The noise, in turn may cause erroneous exchanges of such data and cause various forms of system crashes, system hangs, or other catastrophic failure modes.

It is evident from the above discussion that a need exists for improved structures for decoupling of power and ground signals with respect to other operational logic signals to reduce noise over a broad range of possible frequencies while reducing anti-resonance noise.

### SUMMARY OF THE INVENTION

The present invention solves the above and other problems, thereby advancing the state of the useful arts, by providing a resistive capacitor circuit structure integrating a decoupling capacitor with a resistor to dampen anti-resonance generated signals where the resistor provides high resistance without increasing inductance to thereby improve the suppression of anti-resonance signals. Multiple such improved resistive capacitor structures may then be applied to dampen a broader range of power and ground noise frequencies while dampening the generated anti-resonance noise signals generated from the use of multiple capacitors.

In one aspect, the resistor comprises magnetic and/or low conductivity material, (such as iron, cobalt and nickel), having a small skin depth to provide both high resistance and low inductance. In one aspect, the resistor may be integrated in the structure as one or both of the plates of the capacitor. In another aspect the resistor and capacitor may be discrete but integrated within a single circuit package. In another aspect hereof, the resistive capacitor structure may comprise the power and ground planes of a circuit board as the plates of a capacitor with appropriate magnetic and/or low conductivity material used in all or portions of one or both of the planes serving as plates, or a magnetic/resistive material in the plated through-hole barrel(s) connecting to the plate.

A feature hereof provides a resistive capacitor integrated circuit comprising: a decoupling capacitor for filtering power and ground noise signals from a generated signal path over a range of frequencies; and a series resistance element conductively coupled in series to a plate of the capacitor, wherein the circuit has an electrical series resistance value less than about 2 Ohms and wherein the decoupling capacitor and series resistance element are integrated within a single resistive capacitor circuit package.

Another aspect hereof further provides that the series resistance element comprises a magnetic material having a relative permeability value greater than about 3.

Another aspect hereof further provides that the series resistance element comprises iron.

Another aspect hereof further provides that the series resistance element comprises a low conductivity material having a conductivity value less than about 2.3×10⁷ mhos/m.

Another aspect hereof further provides that the series resistance element is integrated with a plate of the decoupling capacitor.

Another aspect hereof further provides that the series resistance element comprises a plate of the decoupling capacitor.

Another aspect hereof further provides that the series resistive element and decoupling capacitor are discrete components coupled in series.

Another feature hereof provides a system comprising: a first signal path; a second signal path; and a plurality of resistive capacitors coupled in parallel between the first signal path and the second signal path wherein each resistive capacitor includes: a decoupling capacitor for decoupling noise signals in a corresponding range of frequencies; and a series resistance element coupled in series between the first signal path and the decoupling capacitor, wherein the plurality of resistive capacitors are configured to dampen anti-resonance noise.

Another aspect hereof further provides that each series resistance element comprises a magnetic material having a relative permeability value greater than about 3.

Another aspect hereof further provides that each series resistance element comprises iron.

Another aspect hereof further provides that each series resistance element comprises material having a conductivity value less than about 2.3×10⁷ mhos/m.

Another aspect hereof further provides that the second signal path is a power signal path.

Another aspect hereof further provides that the second signal path is a ground signal path.

Another aspect hereof further provides that the first signal path is a power plane of a circuit board and wherein the second signal path is a ground plane of a circuit board and wherein the power plane and the ground plane comprise the plates of the decoupling capacitor of at least one of the resistive capacitors.

Another aspect hereof further provides that the series resistance element of at least one resistive capacitor is integrated with a plate of the decoupling capacitor of the at least one resistive capacitor.

Another aspect hereof further provides that the series resistance element of the at least one resistive capacitor comprises a plate of the decoupling capacitor of the at least one resistive capacitor.

Another aspect hereof further provides that the series resistive element of the at least one resistive capacitor and decoupling capacitor of the at least one resistive capacitor are discrete components coupled in series.

Another feature hereof provides a system in an electrical system power and ground signals, a system comprising: a first signal path; a second signal path; and decoupling means electronically coupled to the first signal path and to the second signal path for decoupling noise on the first signal path from the second signal path and for dampening anti-resonance noise in the system.

Another aspect hereof further provides that the decoupling means further comprise a plurality of resistive capacitor means.

Another aspect hereof further provides that at least one of the resistive capacitor means further comprises: a discrete resistor comprising a magnetic material having a relative permeability value greater than about 3; and a discrete decoupling capacitor coupled in series with the discrete resistor, wherein the discrete resistor and the discrete decoupling capacitor are integrated within a single package.

Another aspect hereof further provides that at least one of the resistive capacitor means further comprises: a discrete decoupling capacitor wherein at least one of the plates of the discrete decoupling capacitor comprises a magnetic material having a relative permeability value greater than about 3.

Another aspect hereof further provides that at least one of the resistive capacitor means further comprises: a discrete decoupling capacitor wherein at least one of the plates of the discrete decoupling capacitor comprises a material having a conductivity value less than about 2.3×10⁷ mhos/m.

### BRIEF DESCRIPTION OF THE DRAWINGS

FIG. 1 is an exemplary resistive capacitor structure in accordance with features and aspects hereof.

FIG. 2 is an exemplary system incorporating resistive capacitors in accordance with features and aspects hereof to dampen anti-resonance noise.

FIG. 3 is a graph representing response of an undampened system devoid of the features and aspects hereof.

FIG. 4 is a graph representing the response of a capacitor improved in accordance with features and aspects hereof

### DETAILED DESCRIPTION OF THE DRAWINGS

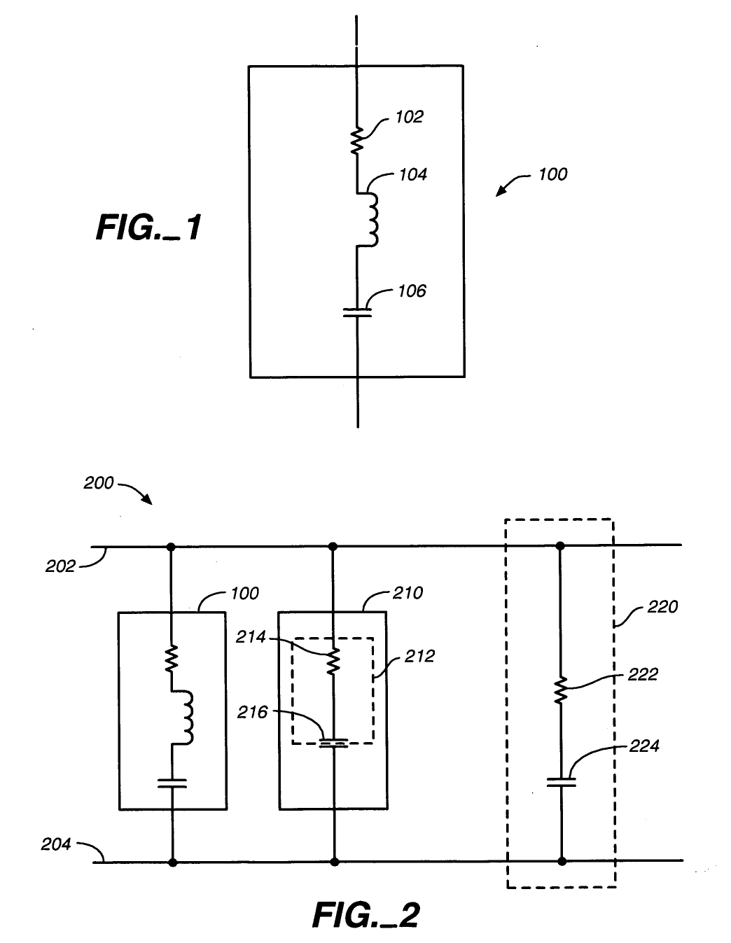

FIG. 1 is a block diagram describing a resistive capacitor 100 embodying features and aspects hereof. Resistive capacitor 100 includes decoupling capacitor 106 and series resistance element 102. The series connection between series resistance element 102 and decoupling capacitor 106 inherently gives rise to an inductance represented as inductor 104. Inductor 104 does not therefore represent an explicit element of the resistive capacitor structure 100 but rather merely acknowledges an inherent attribute of such a circuit structure.

Series resistance element 102 comprises an appropriate resistive material and may be, for example, a magnetic material or other low conductivity material to increase resistance without increasing inductance of the resistive capacitor 100. As used herein, “magnetic” material refers to a material having a relative permeability value greater than about 3. Further, resistance element 102 maybe any low conductivity material. As used herein “low conductivity” refers to material having a conductivity value less than about 2.3×10⁷ mhos/m at 300 degrees K, with the exception of tin and lead or tin-lead alloy, which is currently used as a coating on capacitor terminals to improve solderability. Although series resistance element 102 is still conductive, its magnetic properties provide a heightened skin effect (a fact well known in the art) combined with its lower conductivity (higher resistivity) making the overall material much more resistive than standard copper material. The skin depth (the depth from the outer surface of the material at which current substantially flows) is very small by comparison with non-magnetic materials such as copper, silver, or gold. This smaller skin depth helps maintain lower inductance while increasing resistivity of series resistance element 102.

Resistive capacitor 100 therefore is useful as a decoupling capacitor structure while its enhanced resistivity makes the circuit structure more useful for anti-resonance dampening as compared to decoupling capacitors as presently practiced in the art. By contrast, manufacturers of present decoupling capacitors seek to continually reduce the resistivity of their decoupling capacitor structures. This lowers the electrical series resistance but further exacerbates the anti-resonance effect to amplify noise associated with impedance peaks.

Series resistance element 102 and decoupling capacitor 106 may be discrete elements integrated within a common package 100. Manufacturers may therefore implement features and aspects hereof as a discrete component—a resistive capacitor integrating additional resistance with a decoupling capacitor in a single integrated circuit package. In another aspect hereof, series resistance element 102 may be integrated with decoupling capacitor 106 as one of the plates of decoupling capacitor 106. In other words, one or more of the capacitive plates of capacitor 106 within resistive capacitor 100 may comprise the series resistance element 102 made up of magnetic and/or other low conductivity material as noted above. Further, either or both plates of decoupling capacitor 106 may comprise such resistive material to further enhance the resistance of series resistive capacitor 100.

Those of ordinary skill and the art will readily recognize numerous fabrication techniques for manufacturing such a resistive capacitor 100. In addition, those of ordinary skill in the art will recognize a wide variety of materials possessing the desired magnetic and/or low conductivity properties desirable for series resistance element 102 within resistive capacitor 100. For example, Iron may be used as such a resistive element either as a discrete resistance element 102 coupled in series to a discrete decoupling capacitor 106 or integrated with decoupling capacitor 106 utilizing Iron as the material for one or both plates of decoupling capacitor 106. Numerous equivalent structures and fabrication techniques will be readily apparent to those of ordinary skill in the art.

Another aspect hereof provides for utilizing a plurality of resistive capacitors such as resistive capacitor 100 of FIG. 1 to dampen anti-resonance noise that would otherwise be exacerbated or amplified when multiple decoupling capacitors as presently known are used for a noise filtration application. System 200 of FIG. 2 is a block diagram showing an exemplary system embodying features and aspects hereof where multiple decoupling capacitors may be used for a noise decoupling application.

Resistive capacitors 100, 210, and 220 of FIG. 2 are all coupled in parallel between first signal path 202 and second signal path 204. Such multiple capacitors may be useful, for example, to filter/decouple noise from one signal path coupled to a second signal path. Such multiple decoupling capacitors are known in the art to be useful for filtering a variety of frequencies of such noise. As noted above, such noise may comprise a variety of frequencies and may be generated from a variety of sources. Collectively, as noted above, all such noise generated by all such sources may be referred to herein as SSN or simply “noise”. Each resistive capacitor 100, 210, and 220 of FIG. 2 may be configured to filter a particular range of noise frequencies that collectively comprise SSN in system 200.

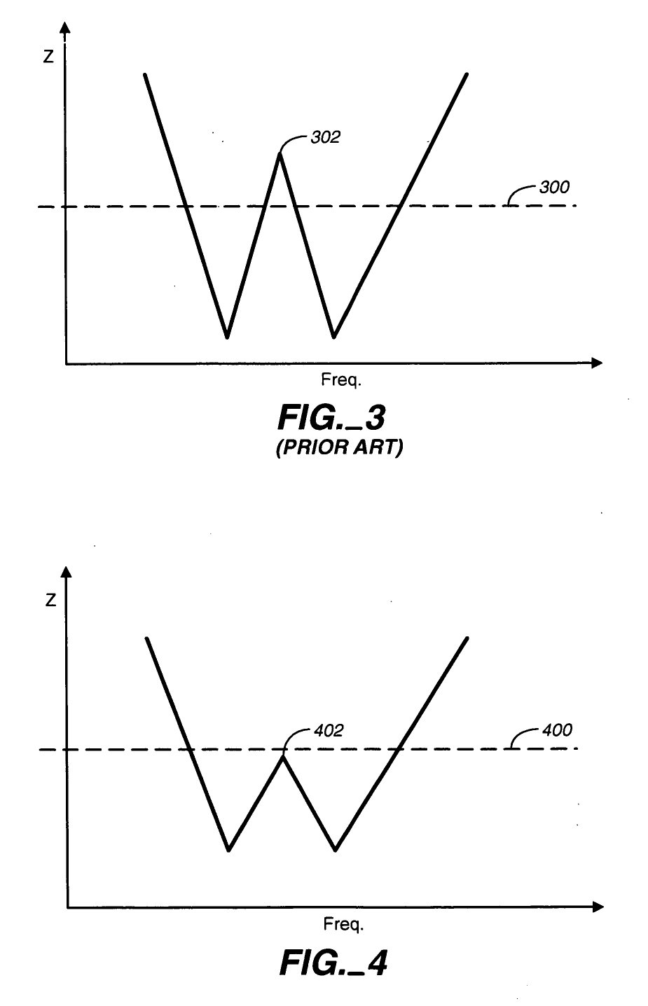

In accordance with features and aspects hereof, each resistive capacitor 100, 210, and 220 is enhanced to provide additional resistance while not increasing inductance so as to thereby dampen anti-resonance noise within system 200. In one exemplary embodiment, the first signal path 202 may be a power signal bus or plane in a circuit board and second signal path 204 may be a ground signal bus or plane. FIGS. 3 and 4 are graphs suggesting the difference in anti-resonance noise in a system with multiple decoupling capacitors between two signal paths implemented with decoupling capacitors as presently practiced (graphed in FIG. 3) and with resistive capacitors in accordance with features and aspects hereof (graphed in FIG. 4).

As shown in the graph of FIG. 3, the Y-axis represents increasing impedance (“Z”) while the X-axis represents increasing frequency. Anti-resonance noise may be exacerbated or amplified by an impedance peak 302 associated with anti-resonance noise) exceeding a target impedance 300. Without the resistive capacitance features and aspects hereof, anti-resonance noise may be generated shown as an exemplary impedance peak 302 exceeding a target impedance level 300. By contrast, system 200 of FIG. 2 utilizing resistive capacitors for decoupling in accordance with features and aspects hereof dampen the anti-resonance noise as indicated by impedance peak 402. By contrast to FIG. 3, impedance peak 402 of FIG. 4 is below and intended target impedance 300. The dampening effect of resistive decoupling capacitors such as those applied in system 200 of FIG. 2 therefore reduces anti-resonance noise in such a system to improve reliability thereof.

Those of ordinary skill in the art will readily recognize that the graphs of FIGS. 3 and 4 are not intended to represent any particular mathematical precision or measured values but rather are intended merely to suggest the benefits achieved in accordance with features and aspects hereof through utilization of resistive capacitor structures for decoupling power and ground signal planes or other signal planes.

Returning again to FIG. 2, other equivalent resistive capacitor structures are shown. Resistive capacitor 100 in FIG. 2 is identical to that of FIG. 1 and represents a resistive capacitor that comprises a discrete series resistance element coupled in series to a discrete decoupling capacitor—both integrated within a single integrated circuit package. By contrast, resistive element capacitor 210 of FIG. 2 is suggestive of an alternative embodiment wherein a resistance element 214 is integral with at least one plate 216 of the decoupling capacitor. Dashed box 212 therefore represents a plate of decoupling capacitor that utilizes appropriate resistive material to achieve the desired anti-resonance dampening features and aspects hereof. Those of ordinary skill in the art will readily recognize that either plate of a decoupling capacitor or both plates of a decoupling capacitor could be so implemented to integrate appropriate resistive material.

Both resistive capacitor 100 and resistive capacitor 210 represent discrete components that may be coupled between a first signal path 202 and a second signal path 204. By contrast, resistive capacitor 220 of FIG. 2 represents another alternative structure wherein the decoupling capacitor is integral with the bus or plane representing the first signal path 202, the second signal path 204, or both signal paths 202 and 204. In other words, the material that comprises first signal path 202 may integrate a first plate of the decoupling capacitor 224 by utilizing appropriate resistive material 222. Thus the signal plane (path 202 or path 204) integrates the series resistance element within a plate of a decoupling capacitor and integrates the plate within the material that comprises the first signal path bus or plane 202. Similarly, a capacitive plate may be integral with the second signal path bus or plane 204. For example, where first signal path 202 represents a power bus or plane of a circuit board and the second signal path 204 represents a ground bus or plane in the same circuit board, a portion, or even the entirety of each plane may be comprised of appropriately selected resistive material so as to incorporate a resistive decoupling capacitor in accordance with features and aspects hereof within the power and ground planes themselves. As noted above, appropriate resistant material may be magnetic material or other low conductivity material that increases resistance while not increasing inductance.

System 200 therefore shows a plurality of equivalent decoupling capacitor structures where any number of decoupling resistive capacitors may be integral within the power and ground planes of the circuit board representing system 200 and any number of discrete, decoupling, resistive capacitors may be coupled between the power and ground planes thereof. Those of ordinary skill in the art will recognize a wide variety of equivalent systems utilizing any number of such discrete resistive capacitors and any number of resistive capacitors integral with the signal buses or planes for which decoupling is intended.

While the invention has been illustrated and described in the drawings and foregoing description, such illustration and description is to be considered as exemplary and not restrictive in character. One embodiment of the invention and minor variants thereof have been shown and described. Protection is desired for all changes and modifications that come within the spirit of the invention. Those skilled in the art will appreciate variations of the above-described embodiments that fall within the scope of the invention. As a result, the invention is not limited to the specific examples and illustrations discussed above, but only by the following claims and their equivalents.

What is claimed is:

1. A resistive capacitor integrated circuit comprising:
a decoupling capacitor for filtering power and ground noise signals from a generated signal path over a range of frequencies; and
a series resistance element conductively coupled in series to a plate of the capacitor,
wherein the circuit has an electrical series resistance value less than about 2 Ohms and wherein the decoupling capacitor and series resistance element are integrated within a single resistive capacitor circuit package.

2. The circuit of claim 1 wherein the series resistance element comprises a magnetic material having a relative permeability value greater than about 3.

3. The circuit of claim 2 wherein the series resistance element comprises iron.

4. The circuit of claim 1 wherein the series resistance element comprises a low conductivity material having a conductivity value less than about 2.3×10⁷ mhos/m.

5. The circuit of claim 1 wherein the series resistance element is integrated with a plate of the decoupling capacitor.

6. The circuit of claim 5 wherein the series resistance element comprises a plate of the decoupling capacitor.

7. The circuit of claim 1 wherein the series resistive element and decoupling capacitor are discrete components coupled in series.

8. A system comprising:
a first signal path;
a second signal path; and
a plurality of resistive capacitors coupled in parallel between the first signal path and the second signal path wherein each resistive capacitor includes:
a decoupling capacitor for decoupling noise signals in a corresponding range of frequencies; and
a series resistance element coupled in series between the first signal path and the decoupling capacitor,
wherein the plurality of resistive capacitors are configured to dampen anti-resonance noise.

9. The system of claim 8 wherein each series resistance element comprises a magnetic material having a relative permeability value greater than about 3.

10. The system of claim 9 wherein each series resistance element comprises iron.

11. The system of claim 8 wherein each series resistance element comprises material having a conductivity value less than about 2.3×10⁷ mhos/m.

12. The system of claim 8 wherein the second signal path is a power signal path.

13. The system of claim 8 wherein the second signal path is a ground signal path.

14. The system of claim 8 wherein the first signal path is a power plane of a circuit board and wherein the second signal path is a ground plane of a circuit board and wherein the power plane and the ground plane comprise the plates of the decoupling capacitor of at least one of the resistive capacitors.

15. The system of claim 8 wherein the series resistance element of at least one resistive capacitor is integrated with a plate of the decoupling capacitor of the at least one resistive capacitor.

16. The circuit of claim 15 wherein the series resistance element of the at least one resistive capacitor comprises a plate of the decoupling capacitor of the at least one resistive capacitor.

17. The circuit of claim 8 wherein the series resistive element of the at least one resistive capacitor and decoupling capacitor of the at least one resistive capacitor are discrete components coupled in series.

18. In an electrical system power and ground signals, a system comprising:
a first signal path;
a second signal path; and
decoupling means electronically coupled to the first signal path and to the second signal path for decoupling noise on the first signal path from the second signal path and for dampening anti-resonance noise in the system.

19. The system of claim 18 wherein the decoupling means further comprise a plurality of resistive capacitor means.

20. The system of claim 19 wherein at least one of the resistive capacitor means further comprises:
a discrete resistor comprising a magnetic material having a relative permeability value greater than about 3; and
a discrete decoupling capacitor coupled in series with the discrete resistor,
wherein the discrete resistor and the discrete decoupling capacitor are integrated within a single package.

21. The system of claim 19 wherein at least one of the resistive capacitor means further comprises:
a discrete decoupling capacitor wherein at least one of the plates of the discrete decoupling capacitor comprises a magnetic material having a relative permeability value greater than about 3.

22. The system of claim 19 wherein at least one of the resistive capacitor means further comprises:
a discrete decoupling capacitor wherein at least one of the plates of the discrete decoupling capacitor comprises a material having a conductivity value less than about 2.3×10⁷ mhos/m.
